(19) United States
(12) Patent Application Publication
(10) Pub. No.: US 2003/0001556 A1
(43) Pub. Date: Jan. 2, 2003

(54) Cable location system using magnetic induction

(75) Inventors: Ziyad H. Doany, Austin, TX (US); Roy B. McCammon, Austin, TX (US)

Correspondence Address: Attention: Nestor F. Ho, Office of Intellectual Property Counsel, 3M Innovative Properties Company, P. O. Box 33427, St. Paul, MN, 55133-3427, US

(73) Assignee: 3M Innovative Properties Company

(21) Appl. No.: 09/892,020

(22) Filed: Jun. 26, 2001

(51) Int. Cl. G01R 19/00; G01V 3/08

(52) U.S. Cl. 324/67; 324/326

(57) ABSTRACT

A method of electronically isolating a conductor by sensing a current signal in the conductor, adjusting the current signal to yield an adjusted signal, and applying the adjusted signal to the conductor to oppose the current signal. Amplifying the signal, as well as phase-shifting the signal may adjust the current signal. The current signal may be sensed using magnetic induction, and the adjusted signal applied to the conductor using magnetic induction as well. The method is carried out using a clamping device that can further evaluate an environment of the conductor, by randomly changing a magnitude and phase of a test signal applied to the conductor, and examining a received signal in response to the changes. A tracking error in the adjusted signal can be handled by predicting a next required phase shift. Prediction coefficients can be calculated utilizing a least means square algorithm. The invention is particularly applicable to the location of obscured (e.g., buried) conductors, and can be incorporated into a cable locator system that applies a trace signal to the target cable to be located. When this trace signal bleeds onto adjacent cables, the clamping devices of the present invention can be used to electronically isolate those cables, i.e., reduce or eliminate unwanted currents arising from coupling with the trace signal. A conventional receiver can then be used to trace the path of the target cable without interference from the nearby cables.

### RELATED APPLICATIONS

The present application is related to co-pending and commonly assigned application entitled “METHOD FOR INDUCED-IMPEDANCE ISOLATION USING MAGNETIC INDUCTION” filed on the same date and by the same inventors, which is hereby incorporated by reference.

### BACKGROUND OF THE INVENTION

1. Field of the Invention

The present invention generally relates to systems and devices for inserting a variable impedance in a conductor, and more particularly to a method and apparatus for locating an obscured (buried) conductor which acts as an antenna to radiate a location signal, wherein the method and apparatus isolate unwanted interference from adjacent conductors.

2. Description of the Related Art

Buried conduits are employed for supplying a wide variety of utilities, including pipelines for gas, water and sewage, and cables for telephone, power and television. It often becomes necessary to locate defective or damaged cables, pipes, etc., in order to repair or replace them. Conversely, it is important to know with as much accuracy as possible the vicinity of such items in order to avoid disturbing them when digging or excavating for other purposes. Above-ground marking devices may be installed immediately after the conduit is buried, but they are often lost, stolen, or destroyed after a short period of use.

There are two primary techniques for the electronic location of such obscured conduits. The first requires that the conduit have (or be) a continuous electrical only have the copper conductors used to transmit the signal or power, but also typically have a ground shield surrounding the cable. The second technique, which may be used on pipes (such as gas and water mains) that do not have such a continuous conductor/wire, requires the previous placement of an object such as an electronic marker adjacent the conduit during its burial.

In the first of these techniques, a test signal (alternating current) is applied, directly or inductively, to the conduit or cable, which then acts as an antenna and radiates the test signal along the length of the conduit. A locating apparatus is then used to detect the presence of the test signal, and the locator may further process the signal to determine the lateral direction to the conductor, and its depth. The earliest cable locators use a single sensor that detects a single null or peak (depending upon the orientation of the sensor) as the unit passes near the cable. Many later devices use two or more sensors that combine the signals to provide an indication of conductor proximity. The most common sensors are ferrite-core antennas, i.e., inductors. A single tracing wire is sometimes buried with a non-conductive utility line. The tracing wire is used as a conductor for an AC signal. The resulting electromagnetic field radiates above ground. The electromagnetic field may be detected with an appropriate receiver, and the underground path of the line thereby determined. A variation of this design provides two or more tracing wires embedded in a length of marking tape.

In the second technique, the electronic markers may be active (e.g., have a battery to supply the signal), but passive markers are more common, having a capacitor and wire coil forming a resonant LC circuit. A given marker has only a single frequency (bandwidth centerline) which is hard-wired, and whose value depends upon the capacitance and inductance of the circuit. A transceiver having a radiating antenna and a pick-up antenna is used to detect passive markers. The radiating antenna intermittently outputs a signal having a frequency tuned to energize the marker. If there is a marker of the appropriate frequency within the vicinity of the transceiver, it absorbs a portion of the signal and re-radiates it. During the periods between signal output by the transceiver, the pick-up antenna listens for any re-radiated signal, and notifies the user if one is found, and usually provides an indication of signal strength. There are hybrid systems wherein a signal is applied to a buried conductor, and coupled through the conductor to one or more markers buried adjacent the conductor. See, e.g., U.S. Pat. Nos. 4,119,908, 4,767,237 and 4,862,088. Also, in U.S. Pat. No. 4,866,388, a marker is used to couple one conductor to another, so that the test signal may be conveyed to the second conductor without a direct connection.

It is particularly convenient to use the first of these techniques with telephone and CATV cables, as these cables surface at various locations in terminal boxes known as pedestals. An amplified signal source may be inductively coupled to a given wire or wire pair at the pedestal. It is possible to directly connect the signal source to the cable where a bare wire is exposed, but this is undesirable as it may result in interference with signals or conversations on the cable. Moreover, direct connection creates a potential shock hazard, and is further unsuitable in instances where no bare wire is exposed. Inductive coupling of the signal to the wire is thus preferable. Induction coils are well known in the art, and are used to generate alternating currents or high voltage pulses in conductors, as well as to create high voltage signals from low-voltage current, as is accomplished in a standard transformer.

The assignee of the present invention, Minnesota Mining & Manufacturing Co. of St. Paul, Minn. (3M), markets several products which incorporate inductive coupling to carry out the first technique. 3M's Dynatel 500 Cable Locator and Dynatel 573 Fault Locator each employ inductive coupling to send the source signal through the cable. The transmitter unit of these devices may simply be placed above the cable, as there is an internal antenna within the transmitter housing that acts as an inductive coil. Alternatively, 3M's Dyna-Coupler accessory may be used to select a single wire for inductive coupling (“Dynatel” and “Dyna-Coupler” are registered trademarks of 3M). The Dyna-Coupler induction tool generally comprises two hingable jaw members that receive two C-shaped (split-ring) cores, respectively. A coil of wire is wrapped around one of the cores and connected to an external jack that is connected to a coil driver.

The most significant disadvantage in the use of a tracing wire or conductive conduit to radiate a locator signal, is that a receiver cannot distinguish the trace conductor from any other conductor in the vicinity which may be carrying the same trace current. Currents can, for example, bleed onto nearby metallic pipes. Also, there are usually many cables accessed in a given telephone/CATV pedestal, and these cables form parallel circuits such that any current applied to one appears (although usually attenuated) on the others, unless all of the cables are completely disconnected at the pedestal. Disconnecting the cable shields at the pedestal before applying the locating signal is certainly possible, for those contractors who are determined to mark the exact spot over the ground that would actually match where the cables are buried, in order to avoid dig-in damage during excavation, but this approach is too time-consuming, and also requires that the cable shields be reconnected after the location procedure is completed. Contract locator technicians normally trace 25 to 35 locates per day. They also have to pay for damage caused by “wrong-marks.” When frequencies at 33 kHz and higher are used under certain conditions, as applied to a telephone cable shield, the signal could flow through the shield to the pairs inside the cable capacitively, and appear on all the cable pairs, since those pairs cannot be disconnected or isolated. If the “far-end” of the cable shield is not grounded, only high frequencies may be applied, which could make the capacitive coupling problem worse. Even the most sophisticated locators do not provide an optimum solution for this congestion problem.

It would, therefore, be desirable to devise an improved system for locating buried conductors using a trace signal, which reduces or isolates the effects of any nearby conductors that might otherwise radiate the same signal and confuse the receiver or the locating technician. It would be further advantageous if the system could solve the congestion problem by providing an easy and fast way to apply the signal to only one conductor at a time, while isolating the others, without physically disconnecting any cable or shields.

### SUMMARY OF THE INVENTION

The present invention is directed to an isolator system for detecting an obscured conductive element. Underground wires and pipes may be traced by injecting a current in the object to be traced. It is then possible to trace the magnetic field caused by the current. Usually, the object being traced is connected to other objects, so that the injected current may travel in those objects also. This may cause a displacement in the apparent position of the desired object or may cause the wrong object to be traced. An alternative is to disconnect the traced object from the other objects, but this takes time, may be impractical, and may even cause damage. The present invention offers a method and an apparatus to prevent current in the other objects without disturbing the locating measurements.

The proposed method includes the step of inductively coupling a trace signal onto the obscured conductor. Then, a voltage is applied in each of the other objects that opposes the unintended flow of current in them. The proposed method and system uses two inductive couplers or clamps on each unintended current path. One coupler provides the opposing voltage and the other senses the residual current. In an alternative embodiment, a single coupler may both sense and provide the opposing signal. A controller adaptively adjusts the amplitude and phase of the opposing voltage to null the residual current.

A drive coupler, drive electronics (i.e., controller and transmitter), sense coupler, receiver, controller and frequency reference comprise a canceller. Several cancellers may share a controller and frequency reference (clock). Each canceller has its own frequency reference and controller. The frequency references are not identical, having differences on the order of a few tens of parts per million (ppm). Each canceller controls the amplitude and phase of its transmitter and has as input, the output of its own receiver. Each canceller is unaware of the other cancellers and of any error in its own frequency reference.

The object to which the transmitter and receiver are inductively coupled forms a loop, generally with ground being part of the loop. One unit is on any one loop. The transmitter induces a voltage in the loop, which generally causes a current. The receiver senses the current in the loop. Due to common impedances, every transmitter may induce voltage and current in every loop. The terms loop, wire, and object may be used interchangeably. It is assumed that each receiver responds only to the current in the loop to which it is attached and not to any other incident fields. Initially, the coupling from a canceller's transmitter to the loop and loop back to its receiver is unknown. The magnitude and phase shift of this coupling from transmitter to receiver will be referred to as the canceller's environment. It is assumed that the strongest signal received by each receiver will be from its associated transmitter. It is also assumed that there is some sort of gain ranging, so that in the simulation, the magnitude of the coupling from the canceller's own transmitter to it's own receiver is set equal to unity.

A system in accordance with the present invention generally comprises several inductive clamp or coupler devices connected to a “smart transmitter.” Each clamp may be used to measure the current in the conductor, apply a signal, and isolate that conductor at the selected frequency In addition, the clamp can be used to determine whether the cable section is grounded or not. The user places a clamp around each cable or cable shield at the beginning of the setup (for example, in a pedestal), then sets the transmitter to locate each section at a time. The transmitter determines whether the amount of signal in the conductor is sufficient for the receiver to detect it. Once the adjacent conductors have been isolated, the primary conductor can be located by detecting the trace signal. When finished, the clamps are disconnected and the pedestal closed. The smart transmitter knows how much current is flowing in each cable section, applies the proper frequency signal to one section only, and indicates to the user what the overall signal distribution is on all the conductors.

The above as well as additional objectives, features, and advantages of the present invention will become apparent in the following detailed written description.

### BRIEF DESCRIPTION OF THE DRAWINGS

The present invention may be better understood, and its numerous objects, features, and advantages made apparent to those skilled in the art by referencing the accompanying drawings.

FIG. 1 is a block diagram of one embodiment of a cable locator system constructed in accordance with the present invention, having a smart transmitter and one or more coupling devices for isolating conductors that are adjacent to a target conductor;

FIG. 2 is a pictorial representation of one of the clamping devices of FIG. 1 as applied to a conductor which is to be isolated from another conductor to be located, illustrating a sensing coil, a canceling coil, and supporting electronics;

FIG. 3 is a perspective view of a cable pedestal with several shielded cables, depicting the exemplary operation of the present invention by applying a locator (trace) signal to one of the cables, while isolating adjacent cables that are inadvertently carrying the same trace signal;

FIGS. 4A and 4B are plan views for one embodiment of a display of the smart transmitter of FIG. 1, showing current readings for different cables before and after cable isolation (clamping); and

FIG. 5 is a chart illustrating the logical flow according to one implementation of the present invention.

FIG. 6 is a

FIG. 7 is a

FIG. 8 is a

The use of the same reference symbols in different drawings indicates similar or identical items.

### DESCRIPTION OF THE PREFERRED EMBODIMENT(S)

The present invention is directed to a method for inserting a high impedance value in-series with a single conductor (or multiple conductors) using magnetic induction, preferably by clamping a fully isolated device around the conductor without making a metallic connection to the conductor. Furthermore, the induced impedance can be varied in magnitude and phase by a control circuit, as explained further below, which adds a programmability feature. When the isolation required is only for a single known frequency rather than a band of frequencies, then higher isolation levels can be obtained and the system is more stable. The description hereafter generally relates to the single-frequency isolation or cancellation configuration. The term “clamp” as used herein refers to electrical clamping of the conductor, and not necessarily to a physical clamping.

If a toroid-shaped small magnetic core is place around a conductor, it will make a 1-turn toroid inductor of inductance in the few micro-Henry range, depending on the shape and dimensions of the core (e.g., 5 μH is equivalent to 0.314 ohms at 10 kHz). This inductive impedance presents itself by generating an opposing potential in-series with the conductor that is proportional to the derivative of the current in the inductor. This voltage “leads” the current by 90 degrees in phase, and is proportional to the frequency. In this invention, the self-inductance function of a passive inductor is emulated and magnified by a gain factor G. By using one toroid for sensing the current in a conductor, amplifying it, and inducing a voltage proportional to it onto the same conductor using a second toroid, an active impedance is inserted into the conductor, in a programmable manner.

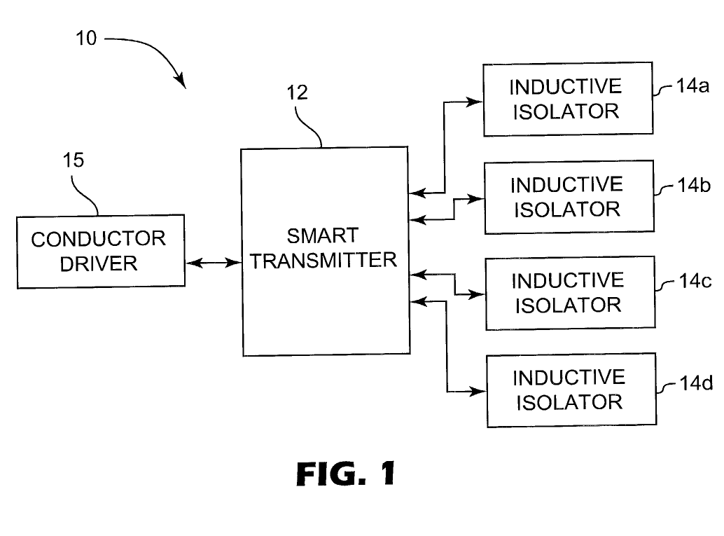

With reference now to the figures, and in particular with reference to FIG. 1, there is depicted one embodiment 10 of a conductor locator system constructed in accordance with the present invention. Conductor locator system 10 is generally comprised of a smart transmitter 12, one or more inductive isolators or clamping devices 14a, 14b, 14c, and 14d, and a conductor driver 15. In the illustrative embodiment, each of the clamping devices 14a, 14b, 14c, 14d is generally identical. As explained further below, the clamping devices are applied to one or more conductors which are to be electronically isolated from another conductor to be located. That is, conductor driver 15 is used to apply the trace signal to the target conductor, and the clamping devices are used to reduce or suppress the trace signal that is inadvertently being carried on adjacent conductors

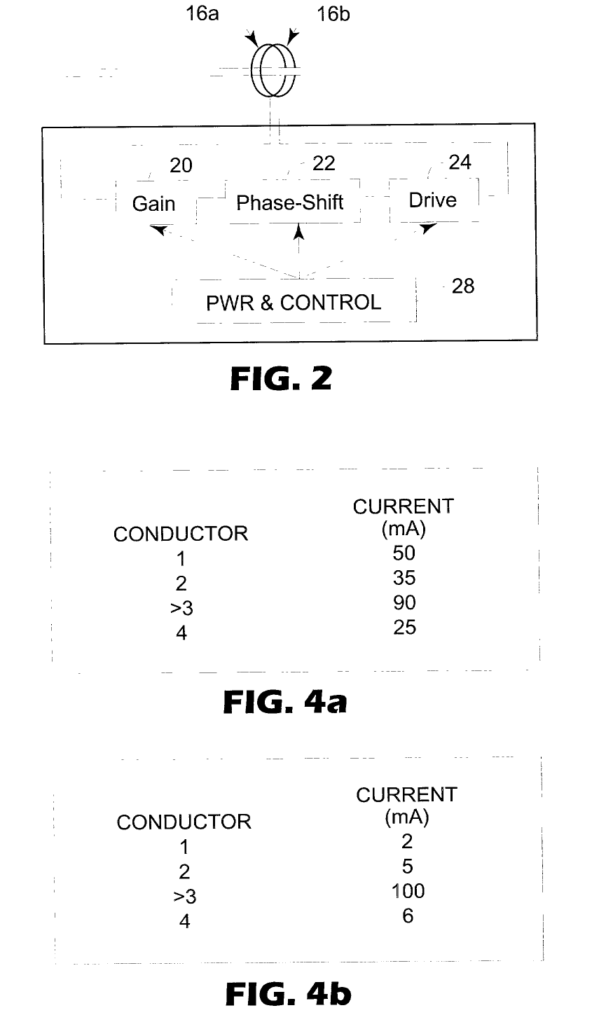

As further seen in FIG. 2, a given clamping device may include two toroidal-shaped cores 16a and 16b each having a few turns, and both surrounding a wire 18 when used during the operation of conductor isolator system 10. One toroid 16a is used to sense the current in the conductor 18 using magnetic induction, and the other toroid 16b is used to induce a signal onto the conductor by magnetic induction. The sensed signal is amplified by a gain circuit 20 and adjusted by a phase-shift circuit 22 with the appropriate phase to oppose or “buck” the sensed current in the conductor. This phase- and gain-adjusted signal is fed to a coil driver circuit 24, which is in turn connected to toroid 16b. The result is the insertion of an effective impedance value for a known amplitude and phase, as determined by the control or feedback transfer function for a certain frequency band. This control function is established using a power and control logic circuit 28. The phase response determines the nature of the transformed impedance from the essentially inductive, passive, 1-turn toroid to the effective resistive or reactive impedance (capacitive or inductive), or a combination thereof. The gain between the sensed signal and the driver circuit, along with the number of turns and the geometry of the cores, determines the impedance amplification.

As an alternative to adjustment of the actual sensed current signal, a local signal may instead be created within isolator 14, and that local signal compared to the sensed current signal. The local signal may then be adjusted appropriately, in response to the comparison of the two signals, to yield the adjusted signal that is then applied to the conductor.

The circuits 20, 22, 24 and 28 may be physically located in a common housing 26 of a given clamping device 14, and each clamping device may generally operate independently, without any knowledge of or interaction with the other clamping devices. Alternatively, these electronics can be incorporated into smart transmitter 12; in this latter case, a common power supply could be used for the circuits associated with all of the coils, and some of the logic functions of control logic 28 may be consolidated.

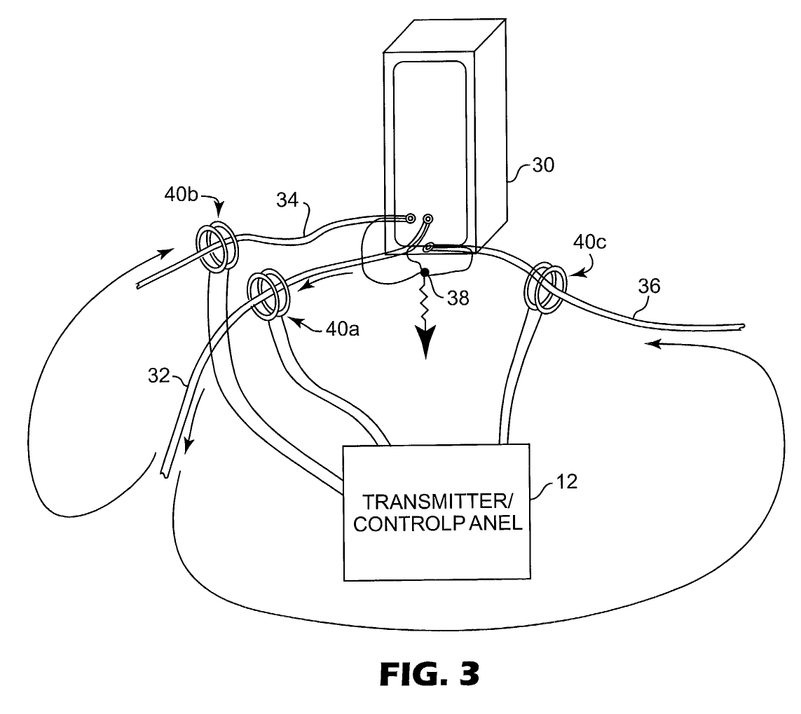

Cores 16a and 16b may be implemented using, e.g., 3M's Dyna-Coupler induction tool (i.e., two separate Dyna-Coupler coils with attached cabling), which allows the induction coils to be placed about an “endless” conductor, i.e., without threading the conductor through the cores. Such a coil pair (receiver/transmitter) may also be connected to conductor driver 15, to allow the system to sense the amount of current flowing through the target conductor as well. In other words, any one of the clamping devices may alternatively operate as the drive coil. This implementation of the invention is illustrated in FIG. 3 (discussed further below). The cables and coil pairs may be color-coded to more easily associate them with a particular clamping device port of smart transmitter 12.

When it is sufficient to provide isolation/cancellation at a known frequency, the system may be simplified in the following manner. A reference frequency may be obtained from smart transmitter 12 as a digital signal, or otherwise derived by phase-locked loop methods if the reference frequency is sent in analog form to the clamping devices. The reference frequency is used to derive or synthesize the driver signal, whereby the phase and amplitude is computing device controlled (e.g., microprocessor) (if the reference frequency is preset and not variable, then smart transmitter 12 need not be utilized with the clamping devices, i.e., a given clamping device 14 may be pre-programmed for that frequency, and thus becomes a standalone conductor isolator system). The sensed current in the conductor may then be filtered from noise, and measured accurately using synchronous detection methods, which will provide a high signal-to-noise ratio. The phase relationship between the current and the voltage may be monitored and stabilized at the proper phase, using the micro-controller within circuit 28. The gain may be measured and controlled, thus varying the induced impedance. Any non-linearities in the system resulting from non-linear components and stray effects (as a function of geometry, frequency, temperature, signal level, etc.) may be more easily compensated for in a synchronous single-frequency system, as compared to a medium or wide-band system wherein more complex equalization may be necessary. Non-linearities in a single frequency system may by easily compensated for, thus allowing higher gains and therefore, higher isolation impedances.

Heterodyne techniques are used in the receiver 16a and transmitter 16b to achieve narrow bandwidths and favorable signal-to-noise ratios. The signals received from toroid 16a are mixed with the output of a beat frequency oscillator (BFO). If a sinusoidal current is in the loop, control logic 28 will receive a sinusoid of a frequency equal to the transmitted frequency minus the BFO frequency. The BFO frequency is a known fraction, r, of the transmit frequency, hence when a clamping device's own transmitter is down converted, it will be to a known frequency, such as 2 kHz. The output of the receiver is sampled at four times the down converted frequency, or 8 kHz in this example. The receiver has a bandwidth of about 500 Hz, so there is considerable correlation from one sample to the next. Accordingly, once approximately every 2 milliseconds, four successive samples are accepted for processing, with the others being discarded.

When a clamping device is first activated, it spends about one second evaluating its environment. The term environment may include such electrical characteristics as coupling impedances, signal attenuation, or noise. The evaluation is performed by randomly changing the magnitude and phase of its transmitter and examining the resulting received signal. Once the environment has been estimated, the clamping device begins active cancellation. It adaptively adjusts the amplitude and phase of its transmitter to cancel any correlated signal received by the receiver. If there is a difference in the frequency reference of the clamping device and the incoming signal, the clamping device continuously changes the phase of its transmitter.

A tracking error may develop. If so, this error can be decreased by predicting the next required phase shift. Accordingly, once the clamping device starts active canceling, it also starts estimating the prediction coefficients. This process takes about one second and, when complete, the clamping device then uses both adaptive cancellation and prediction, and continues to refine the prediction coefficients. In typical operation, a clamping device is fully canceling and predicting in less than three seconds after initialization.

In the illustrative embodiment, a least-means-square (LMS) algorithm is used to evaluate the environment, carry out the adaptive canceling, and estimate the prediction coefficients. The LMS algorithm used is described below:

I. Notation and Definitions:

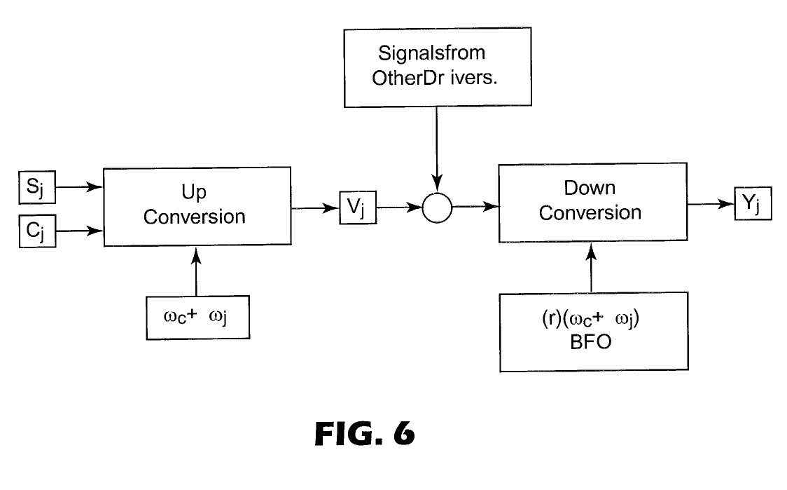

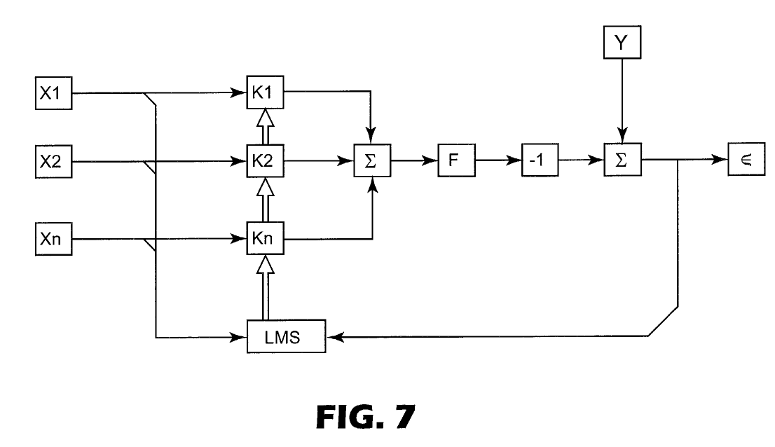

Referring to FIGS. 6-8,

Σᵢ=sum over all i

Σ_{i≠j}=sum over all i except for i=j

ω_{c}=nominal transmit frequency, typically 200 kHz or 32.768 kHz

ωᵢ, ωⱼ=frequency error of the i'th and j'th unit.

ω_{c}+ω=actual transmit frequency of the i'th unit.

r(ω_{c})=nominal frequency of BFO (beat frequency oscillator).

r(ω_{c}+ωⱼ)=actual frequency of BFO of j'th unit.

(1−r)(ω_{c})=nominal down converted frequency.

ωⱼⱼ=(1−r)(ω_{c}+ωⱼ)

Dⱼᵢ=net gain from the i'th transmitter to the j'th receiver.

αⱼᵢ=net phase shift from the i'th transmitter to the j'th receiver.

Sᵢ, Cᵢ=signals used to control the i'th transmitter.

Sⱼ, Cⱼ=signals used to control the j'th transmitter.

vⱼ=output of j'th transmitter

yⱼ=input to j'th controller from j'th receiver.

II. Equations

The relationship between Sⱼ, Cⱼ, and the output v; is given by:

vⱼ˜Cⱼcos[(ω_{c}+ωⱼ)t]+Sⱼsin[(ω_{c}+ωⱼ)t} 1)

The input to the j'th receiver is just a linear combination of the outputs of all the transmitters down converted by the j'th BFO.

yⱼΣᵢ{DⱼᵢC_{I} cos[(ω_{c}+ωⱼ)t+(ωᵢ−ωⱼ)t+αⱼᵢ]+DⱼᵢS_{I} sin[(ω_{c}+ωᵢ)t−r(ω_{c}+ωⱼ)t+αⱼᵢ]} 2)

adding and subtracting ωⱼ gives:

yⱼ=Σᵢ{DⱼᵢCᵢcos[(1−r(ω_{c}+ωⱼ)t+(ωᵤ−ωⱼ)t+αⱼᵢ]+DⱼᵢSᵢ sin[(1−r)(ω_{c}+ωⱼ)t+(ωᵢ−ωⱼ)t+αⱼᵢ]} 3)

Defining some convenient terms gives the following equation, which still merely expressed that the input of the j'th receiver is just a linear combination of the outputs of all the transmitters:

Let ωⱼⱼ=(1−r)(ω_{c}+ωⱼ)

Let ωⱼᵢ=ωⱼⱼ+(ωᵢ−ωⱼ)

yⱼ=Σᵢ{DⱼᵢCᵢ cos(ωⱼᵢt+αⱼᵢ)+DⱼᵢSᵢ sin(ωⱼᵢt+αⱼᵢ)} 4)

Using trig identities for sum and differences:

yⱼ=Σᵢ{DⱼᵢCᵢ[cos(ωⱼᵢt)cos(αⱼᵢ)−sin((ωⱼᵢt)sin(αⱼᵢ)]+DⱼᵢSi[sin(ωⱼᵢt)cos(αⱼᵢ)+cos((ωⱼᵢt)sin(αⱼᵢ)]} 5)

Rearranging terms and making some more convenient definitions:

Let Rⱼᵢ=Dⱼᵢ cos(αⱼᵢ)

Rⱼ=Rⱼⱼ

Qⱼᵢ=Dⱼᵢsin(αⱼᵢ)

Qⱼ=Qⱼⱼ

yⱼ=Σᵢ{(Rⱼᵢ)(Cᵢ cos(ωⱼᵢt)+Sᵢ sin(ωⱼᵢt))+(Qⱼᵢ)(Sᵢ cos(ωⱼᵢt)−Cᵢ sin(ωⱼᵢt))} 6)

Separating the “j” terms from the “non j” terms gives:

yⱼ=Σ_{i≠j}{Rⱼᵢ(Cᵢ cos(ωⱼᵢt)+S_{I} sin(ωⱼᵢt))+Qⱼᵢ(Sᵢ cos(ωⱼᵢt)−Cᵢ sin(ωⱼᵢt))}+Rⱼ[Cⱼ cos(ωⱼⱼt)+Sⱼ sin(ωⱼⱼt)]+Qⱼ[Sⱼ cos(ωⱼⱼt)−Cⱼ sin(ωⱼⱼt)] 7)

Since the terms in brackets ([ ]) are known to the j'th controller, this equation is in canonical form for adaptive estimation of Rⱼ and Qⱼ by the LMS algorithm. Note, it will be assumed that samples of yⱼ are taken every quarter cycle of the down converted frequency ωⱼⱼ. Thus, cos(ωⱼⱼt) and sin(ωⱼⱼt) cycle through the following values (1,0), (0,1), (−1,0), (0,−1). Although this is in canonic form, its adaptation is hindered by the signals from the other drivers. To eliminate this, yj and the bracketed quantities are filtered. The filter is nothing more than subtracting previous value from the current value. The delay is always an integer number of cycles of ωⱼⱼ. Old values of yj are stored, but old values of the bracket quantities can be calculated.

yⱼ−yⱼ^{old}=Rⱼ[(Cⱼ−Cⱼ^{old})cos(ωⱼⱼt)+(Sⱼ−Sⱼ^{old})sin(ωⱼⱼt)]+Qⱼ[(Sⱼ−Sⱼ^{old})cos(ωⱼⱼt)−(CⱼCⱼ^{old})sin(ωⱼⱼt)]+other terms 8)

The LMS algorithm for this is given by

Δ<=yⱼ−yⱼ^{old}

Rⱼ′<=Rⱼ′+(μ₁)(Δ)[(Cⱼ−Cⱼ^{old})cos(ωⱼⱼt)+(Sⱼ−Sⱼ^{old})sin(ωⱼⱼt)]

Qⱼ′<=Qⱼ′+(μ₁)(Δ)[(Sⱼ−Sⱼ^{old})cos(ωⱼⱼt)−(C_{j-C}ⱼ^{old})sin(ωⱼⱼt)] 9)

In order to adapt Cⱼ and Sⱼ, equation 6 is rearranged to give:

yⱼ=Σᵢ{Cᵢ(Rⱼᵢ cos(ωⱼᵢt)−Qⱼᵢ sin(ωⱼᵢt))+Sᵢ(Rⱼᵢ sin(ωⱼᵢt)+Qⱼᵢ cos(ωⱼᵢt))} 10)

separating the “j” terms from the “non j” terms and substituting Rⱼ′ and Qⱼ′ for Rⱼ and Qⱼ:

yⱼ=Σ_{i≠j}{(Cᵢ)(Rⱼᵢ cos(ωⱼᵢt)−Qⱼᵢ sin(ωⱼᵢt))+(Sᵢ)(Rⱼᵢ sin(ωⱼᵢt)+Qⱼᵢ cos(ωⱼᵢt))}+(Cⱼ)[Rⱼ′ cos(ωⱼⱼt)−Qⱼ′ sin(ωⱼⱼt)]+(Sⱼ)[Rⱼ′ sin(ωⱼⱼt)+Qⱼ′ cos(ωⱼⱼt)] 11)

This is the form used to adapt Cⱼ and Sⱼ. Since Rⱼ′ and Qⱼ′ are known, the quantities in brackets ([ ]) are known and this equation is in canonical form for the LMS adaptive algorithm.

The LMS algorithm for this is given by:

Cⱼ<=Cⱼ−(μ₂)(yⱼ)[Rⱼ′ cos(ωⱼⱼt)−Qⱼ′ sin(ωⱼⱼt)]

Sⱼ<=Sⱼ−(μ₂)(yⱼ)[Rⱼ′ sin(ωⱼⱼt)+Qⱼ′ cos(ωⱼⱼt)] 12)

Once adaptive canceling has converged, if the master transmitter has a frequency different from the j+th canceler, the optimum values of Cj and Sj will advance along an arc of a circle at a rate of φ per update. Thus if Cj and Sj are represented by:

Cⱼ=M cos(θ)

Sⱼ=M sin(θ)

at the next update Cj and Sj will be given by,

Cⱼ^{new}=M cos(θ+φ)

=M cos(θ)cos(φ)−M sin(θ)sin(φ)

=Cⱼ cos(φ)−Sⱼ sin(φ)

Sⱼ^{new}=M sin(θ+φ)

=M sin(θ)cos(φ)+M cos(θ)sin(φ)

=Sⱼ cos(φ)+Cⱼ sin(φ) 14)

Defining:

K_{c}=cos(φ)

Kₛ=sin(φ)

Then,

Cⱼ^{new}=K_{c}(Cⱼ)−Kₛ(Sⱼ)

Sⱼ^{new}=Kₛ(Cⱼ)+K_{c}(Sⱼ) 15)

applying this to previous values of Sj and Cj, we get

Cⱼ=K_{c}(Cⱼ^{old})−Kₛ(Sⱼ^{old})

Sⱼ=Kₛ(Cⱼ^{old})+K_{c}(Sⱼ^{old}) 16)

K_{c} and Kₛ can now be estimated by the LMS algorithm.

Δ_{c}<=Cⱼ−(K_{c}(Cⱼ^{old})−Kₛ(Sⱼ^{old}))

Δₛ<=Sⱼ−(Kₛ(Cⱼ^{old})+K_{c}(Sⱼ^{old}))

K_{c}<=K_{c}+μ₂[Δ_{c}(Cⱼ^{old})+Δₛ(Sⱼ^{old})]

Kₛ<=Kₛ+μ₂ [Δₛ(Cⱼ^{old})−Δ_{c}(Sⱼ^{old})] 17)

III. Algorithm

A clamping device has three major states: Training, Canceling (not training) and Canceling with Prediction. Training and Canceling do not occur at the same time.

Training (Perform Once Every 2 Milliseconds)

Perform 4 iterations of equations 9, save old values, randomly set Cⱼ and Sⱼ.

Δ<=yⱼ¹−yⱼ^{old1}

Rⱼ′<=Rⱼ′+(μ₁)(Δ)(Cⱼ−Cⱼ^{old})

Qⱼ′<=Qⱼ′+(μ₁)(Δ)(Sⱼ−Sⱼ^{old})

yⱼ^{old1}<=yⱼ¹

Δ<=yⱼ²−yⱼ^{old2}

Rⱼ′<=Rⱼ′+(μ₁)(Δ)(Sⱼ−Sⱼ^{old})

Qⱼ′<=Qⱼ′+(μ₁)(Δ)(Cⱼ^{old}−Cⱼ)

yⱼ^{old2}<=yⱼ²

Δ<=yⱼ³−yⱼ^{old3}

Rⱼ′<=Rⱼ′+(μ₁)(Δ)(Cⱼ^{old}−Cⱼ)

Qⱼ′<=Qⱼ′+(μ₁)(Δ)(Sⱼ^{old}−Sⱼ)

yⱼ^{old3}<=yⱼ³

Δ<=yⱼ⁴−yⱼ^{old4}

Rⱼ′<=Rⱼ′+(μ₁)(Δ)(Sⱼ^{old}−Sⱼ)

Qⱼ′<=Qⱼ′+(μ₁)(Δ)(Cⱼ−Cⱼ^{old})

yⱼ^{old4}<=yⱼ⁴

Cⱼ^{old}<=Cⱼ

Sⱼ^{old}<=Sⱼ

Cⱼ<=random( )

Sⱼ<=random( )

Effort: 8 eight bit multiply, 8 sixteen bit multiply, 20 sixteen bit add/subtract operations and two random number generations every 2 milliseconds.

Canceling (with or without Prediction) (Perform Once Every 2 Milliseconds)

Perform 4 iterations of equations 12, 1 iteration of equations 17, save old values, update Cⱼ and Sⱼ, if Predicting then also 1 iteration of equations 15.

Cⱼ^{next}<=0

Sⱼ^{next}<=0

Cⱼ^{next}<=Cⱼ^{next}−(yⱼ¹)(Rⱼ′)

Sⱼ^{next}<=Sⱼ^{next}(yⱼ¹)(Qⱼ′)

Cⱼ^{next}<=Cⱼ^{next}−(yⱼ²)(−Qⱼ′)

Sⱼ^{next}<=Sⱼ^{next}−(yⱼ²)(Rⱼ′)

Cⱼ^{next}<=Cⱼ^{next}−(yⱼ³)(−Rⱼ′)

Sⱼ^{next}<=Sⱼ^{next}−(yⱼ³)(−Qⱼ′)

Cⱼ^{next}<=Cⱼ^{next}−(yⱼ⁴)(Qⱼ′)

Sⱼ^{next}<=Sⱼ^{next}−(yⱼ⁴)(−Rⱼ′)

Cⱼ^{old}<=Cⱼ

Sⱼ^{old}<=Sⱼ

Δ_{c}<=(μ₂(Cⱼ^{next})

Δₛ<=(μ₂)(Sⱼ^{next})

Cⱼ^{pred}<=K_{c}(Cⱼ)−Kₛ(Sⱼ)

Sⱼ^{pred}<=Kₛ(Cⱼ)+K_{c}(Sⱼ)

Cⱼ<=Cⱼ^{pred}+Δ_{c}

Sⱼ<=Sⱼ^{pred}+Δₛ

IF (Predicting) THEN

K_{c}<=K_{c}+μ₃[Δ_{c}(Cⱼ^{old})+Δₛ(Sⱼ^{old})]

Kₛ<=Kₛ+μ₃[Δₛ(Cⱼ^{old})−Δ_{c}(Sⱼ^{old})]

Effort: 8 eight bit multiply, 10 sixteen bit multiply, 16 sixteen bit add/subtract operations and two random number generations every 2 milliseconds.

Referring now to FIG. 3, one exemplary use of the conductor isolator system of the present invention is to trace a cable that is terminated in an aboveground pedestal 30. In this example, three cables 32, 34 and 36 are shown terminated at pedestal 30. Each of the cables has a shield that is connected to an earth or common ground connection 38 provided at pedestal 30. Smart transmitter 12 has three coil pairs 40a, 40b and 40c connected thereto. As described above, each coil pairs has two toroids 16a and 16b. Coil pair 40a surrounds cable 32 (the target cable to be located), and thus applies the trace signal to cable 32, while coil pairs 40b and 40c act as cancelers, surrounding cables 34 and 36, respectively.

Due to return ground currents, and as indicated by the dashed lines in FIG. 3, when the trace signal is applied by coil pair 40a to the shield of cable 32, it bleeds onto the cable shields of cables 34 and 36 as well (prior to activation of the clamping devices). As further shown in FIGS. 4A and 4B, a display (e.g., liquid crystal display) 42 built-in to transmitter 12 can provide an indication of the current flowing in the cables at the reference frequency.

In the illustration of FIG. 4A, where the trace signal is being applied to the target conductor (by coil pair 40a via transmitter port number 3 in this example), but prior to isolation of the adjacent conductors, the display informs the operator of the relatively high currents that coupled onto the adjacent conductors. Specifically, the trace signal applied to cable 32 is generating a trace current of about 90 milli-amps (mA), while currents in the adjacent conductors are generated at 50 mA (cable 34, measured by coil pair 40b via transmitter port number 1), 35 mA (cable 36, measured by coil pair 40c via transmitter port number 2), and 25 mA (a fourth cable not shown in FIG. 3, measured by another coil pair via transmitter port number 4). A caret mark 44 may be used on display 42 to confirm to the operator which cable port is being used as the trace signal applicator.

In the illustration of FIG. 4B, the clamping devices have been activated, isolating the adjacent cables, i.e., substantially reducing the unwanted currents in those cables. The current in cable 34 (transmitter port 1) has been lowered from 50 mA to 2 mA, the current in cable 36 (transmitter port 2) has been lowered from 35 mA to 5 mA, and the current in the fourth cable (transmitter port 4) has been lowered from 25 mA to 6 mA. After the operator visually confirms the relative isolation of the non-target cables, the locate operation can begin using a conventional above-ground receiver. Those skilled in the art will appreciate that the information shown in display 42 of transmitter 12 could instead be spread out over each of the clamping devices, i.e., in the embodiment of FIG. 2 wherein each clamping device has its own separate electronics, each device may also be provided with a separate display to show the sensed current in each associated conductor.

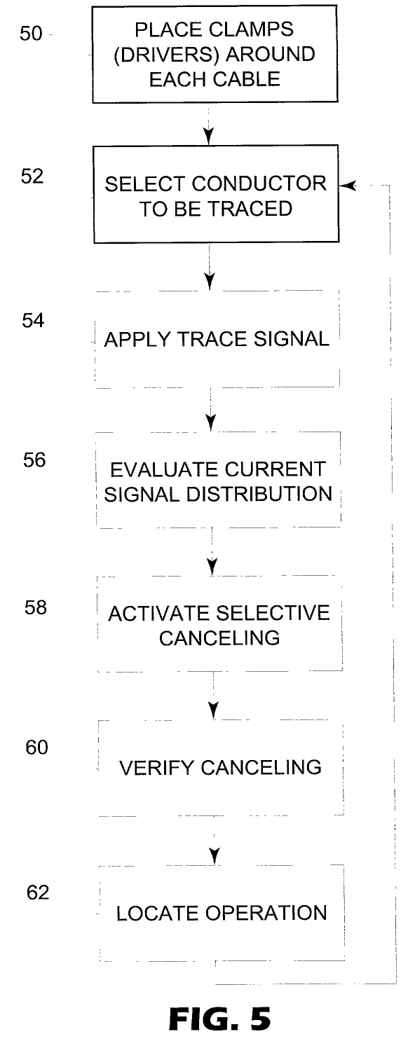

Operation of the invention may be further understood with reference to the flow chart of FIG. 5. The procedure begins with the placement of the clamping devices (or drivers) about each of the cables of concern (step 50). One of the conductors is selected for tracing, via a user interface (keyboard) provided on smart transmitter 12 (step 52). The operator then initiates application of the trace signal to the target cable (step 54). The operator may want to evaluate the current signal distribution across all of the conductors at this point, by referring to the current values shown in display 42 (step 56). Presuming that the sensing coils appear to be functioning properly (i.e., the inductive coupling devices have been properly attached to the cables and all connections are complete), the operator will then activate the cancellation of the adjacent conductors (step 58). This activation may be selective, i.e., less than all of the clamping devices may be utilized for a particular locate operation. The operator can verify that the currents in the adjacent conductors are being cancelled, again by referring to the output of display 42 (step 60). Location of the target cable may then commence (step 62). The process may be repeated with different target cables, returning to step 52.

The term “computing device” includes a device having at least one central processing unit (CPU) and a memory device, wherein the CPU is adapted to process data that can be stored in the memory device before and/or after processing. Common examples of a computing device include personal computer, palm computing device, notebook computer, server, or mainframe. Also included within the definition of computing device is a system of multiple computers networked together such that processing and/or storage activities on the computers are coordinated. Also included in the definition of computing device is a system of devices networked together such that each device may not be a computer in its own right, but in combination, the networked devices achieve the functionality of a computer having at least one CPU and at least one memory device. For example, components of a computing device may be connected across the Internet.

Although the invention has been described with reference to specific embodiments, this description is not meant to be construed in a limiting sense. Various modifications of the disclosed embodiments, as well as alternative embodiments of the invention, will become apparent to persons skilled in the art upon reference to the description of the invention. It is therefore contemplated that such modifications can be made without departing from the spirit or scope of the present invention as defined in the appended claims.

What is claimed is:

3. A locator system for tracing an obscured electrical conductor, wherein the obscured electrical conductor is electrically coupled to at least one other conductor, the locator system comprising:
a signal generator capable of producing a trace signal;
at least one sensor that measures a residual current signal caused by the trace signal on the at least one other conductor;
at least one second inductive coupler inductively coupled to the at least one other conductor;
a controller circuit having an input coupled to the at least one sensor and an output coupled to the at least one second inductive coupler, wherein the controller circuit adaptively provides an opposing voltage to the at least one second inductive coupler that cancels the residual current signal.

2. The cable locator of claim 1, further comprising a first inductive coupler electrically coupled to the signal generator, the inductive clamp capable of introducing the trace signal onto the obscured electrical conductor;

3. The cable locator system of claim 1, further comprising a detector element that locates the obscured conductor carrying the trace signal.

4. The cable locator system of claim 1, wherein the controller circuit comprises a computing device.

5. The cable locator system of claim 1, wherein the controller circuit amplifies the residual current signal and induces the opposing voltage proportional to the residual current onto the at least one other conductor.

6. The cable locator system of claim 5, wherein the controller circuit adaptively adjusts the amplitude and phase of the opposing voltage to null the residual current.

7. The cable locator system of claim 1 further comprising a reference signal transmitter coupled to the at least one other conductor, wherein the sensor measures a magnitude and phase shift of the coupling from transmitter to sensor and the controller circuit adaptively adjusts the opposing voltage accordingly.

8. A canceller for canceling an unwanted signal in a conductor comprising:
a) a drive coupler that inductively couples to the conductor;
b) a sense coupler configured for inductively sensing the conductor;
c) a receiver having an input coupled to the sense coupler
d) a transmitter having a drive signal output coupled to the drive coupler; and
e) a controller coupled to the receiver and the transmitter, wherein the controller adaptively adjusts the amplitude and phase of the drive signal of the transmitter to cancel the unwanted signal received by the receiver.

9. The canceller of claim 9, further comprising
a) a frequency reference, wherein the reference frequency is used by the controller to create the driver signal.

10. The canceller of claim 9, wherein the controller is a computing device.

11. The canceller of claim 9, wherein the drive and sense couplers comprise magnetic cores, wherein the sense coupler senses current in the conductor and the drive coupler amplifies the current and induces a voltage proportional to the current onto the conductor.

12. The canceller of claim 9, wherein said controller creates a local signal;
compares the local signal to a sensed current signal; and
adjusts the local signal to yield an adjusted signal.

13. A cable locator system comprising:
a) means for placing a trace signal on a first conductor;
b) means for reducing any unwanted currents in a second conductor which arise from coupling with the trace signal; and
c) means for locating a path of the first conductor by detecting the trace signal.

14. The cable locator system of claim 13 wherein said placing means inductively couples the trace signal to the first conductor.

15. The cable locator system of claim 13 wherein said locating means receives an electromagnetic signal emitted by the first conductor using an induction coil receiver.

16. The cable locator system of claim 13 wherein said reducing means includes:
a) means for sensing a current signal associated with the unwanted current in the second conductor;
b) means for deriving an adjusted signal from the sensed current signal; and
c) means for applying the adjusted signal to the second conductor to oppose the unwanted current.

17. The cable locator system of claim 13 further comprising means for evaluating an environment of the second conductor.

18. The cable locator system of claim 13 wherein said reducing means includes:
a) an inductive sensing coil attached to the second conductor; and
b) an inductive transmitter coil attached to the second conductor.

19. The cable locator system of claim 16 wherein said deriving means amplifies the current signal, and shifts the phase of the current signal.
